(19) United States
(12) Patent Application Publication
(10) Pub. No.: US 2022/0357424 A1
(43) Pub. Date: Nov. 10, 2022

(54) Systems and Methods for Providing a Gapless LiDAR Emitter Using a Laser Diode Bar

(71) Applicant: Argo AI, LLC, Pittsburgh, PA (US)

(72) Inventors: Evgenii Y. Kotelnikov, Cranbury, NJ (US); Igor Kudryashov, Cranbury, NJ (US)

(21) Appl. No.: 17/462,724

(22) Filed: Aug. 31, 2021

Related U.S. Application Data
(60) Provisional application No. 63/183,860, filed on May 4, 2021.

(51) Int. Cl. G01S 7/484; H01S 5/40; G01S 17/931

(52) U.S. Cl. CPC G01S 7/484; H01S 5/4025; G01S 17/931

(57) ABSTRACT

Implementing systems and methods for operating a LiDAR system. The methods comprise: supplying current from a laser diode bar driver of the LiDAR system to a light source of the LiDAR system; passing the current through a laser diode bar of the light source (the laser diode bar comprising a plurality of laser diodes electrically connected in series); emitting a light beam from the light source when current is passing through the plurality of laser diodes; and/or receiving light reflected off an object.

### RELATED APPLICATION AND CLAIM OF PRIORITY

This patent document claims priority to U.S. Provisional Patent Application No. 63/183,860 filed May 4, 2021, the disclosure of which is fully incorporated into this document by reference.

### BACKGROUND

### Statement of the Technical Field

The present disclosure relates generally to Light Detecting and Ranging (LiDAR) systems. More particularly, the present disclosure relates to implementing systems and methods for providing an emitter using a laser diode bar.

### Description of the Related Art

LiDAR systems are used in various applications. One application for LiDAR systems is autonomous vehicles. Autonomous vehicles may use LiDAR systems to measure the distance from the autonomous vehicle to surrounding objects. To accomplish this task, the LiDAR system illuminates an object with light and measures the light reflected from the object with a sensor. The reflected light is used to determine features of the object that reflected it and to determine the distance the object is from the autonomous vehicle. LiDAR systems also may be used in other applications, such as in aircraft, ships, mapping systems, and others.

### SUMMARY

The present document relates to systems and methods for operating a LiDAR system. The methods comprise: supplying current from a laser diode bar driver of the LiDAR system to a light source of the LiDAR system; passing the current through a laser diode bar of the light source (the laser diode bar comprising a plurality of laser diodes electrically connected in series); emitting a light beam from the light source when current is passing through the plurality of laser diodes; and/or receiving light reflected off an object.

Operations of the plurality of laser diodes are automatically synchronized in time. The light beam may have a beam divergence less than or equal to one degree in a first direction, and a beam divergence greater than or equal to ten degrees in a second different direction. The laser diode driver is connected to the laser diodes. A Thermal Electric Cooler (TEC) power of the LiDAR system may be decreased by locating the laser diodes on an active cooling component and locating the laser diode bar driver remote from the active cooling component. The laser diodes can thus be cooled independently from the laser diode bar driver.

The present document also concerns LiDAR systems. The LiDAR systems comprise: a light emitter system configured to emit light therefrom and comprising a diode laser bar formed of a plurality of laser diodes; and a driver circuit configured to supply current to the light emitter system. The light is generated by the light emitter system as the current passes through the diode laser bar. The driver circuit is connected to the laser diode bar. The laser diodes may be electrically connected to each other in series and cooled independently from the driver circuit. Operations of the laser diodes are automatically synchronized.

Each laser diode comprises a stack of layers disposed on a semiconductor substrate formed of an insulative material. The stack of layers can comprise a first layer formed of an N-type semiconductor material disposed on the semiconductor substrate, a second layer formed of an intrinsic compound semiconductor material disposed on the first layer, and a third layer formed of a P-type semiconductor material disposed on the second layer. An insulative material and a conductive material are disposed on the stack of layers to electrically connect a first laser diode of the plurality of laser diodes in series with a second laser diode of the plurality of laser diodes. The conductive material connects the P-type semiconductor material of the first laser diode to the N-type semiconductor material of the second laser diode.

The present document further concerns systems. The systems comprise (i) a LiDAR system configured to generate LiDAR data sets and (ii) a computing device configured to issue a command to cause a vehicle to perform operations based on the LiDAR data sets. The operations can include, but are not limited to, autonomous driving operations (e.g., changing directions of travel, speed, amount of acceleration, etc.).

The LiDAR system comprises: a driver circuit configured to supply current to a light emitter system. The light emitter system comprises a diode laser bar formed of laser diodes. The laser diodes may be electrically connected to each other in series. Light is generated when the current passes through the laser diode bar. The driver circuit may be connected to the laser diode bar. The laser diode bar can be cooled independently from the driver circuit.

Each laser diode comprise a stack of layers disposed on a semiconductor substrate formed of an insulative material. The stack of layers may comprise a first layer formed of an N-type semiconductor material disposed on the semiconductor substrate, a second layer formed of an intrinsic compound semiconductor material disposed on the first layer, and a third layer formed of a P-type semiconductor material disposed on the second layer. An insulative material and a conductive material are disposed on the stack of layers to electrically connect a first laser diode of the plurality of laser diodes in series with a second laser diode of the plurality of laser diodes. The conductive material connects a P-type semiconductor material of the first laser diode to a N-type semiconductor material of the second laser diode.

### BRIEF DESCRIPTION OF THE DRAWINGS

The present solution will be described with reference to the following drawing figures, in which like numerals represent like items throughout the figures.

FIG. 1 provides an illustration of a system.

FIG. 2 is an illustration of an illustrative architecture for a vehicle.

FIG. 3 is an illustration of an illustrative architecture for a LiDAR system employed by the vehicle shown in FIG. 2.

FIGS. 4-5 provide illustrations of that are useful for understanding operations of the LiDAR system in object detection applications.

FIG. 6 provides a table showing illustrative parameters for a laser diode bar of a LiDAR system.

FIG. 7 provides an illustrative architecture for a laser diode bar.

FIG. 8 provides an illustration showing a circuit comprising the laser diode bar of FIG. 7.

FIG. 9 provides an illustration of an architecture for a controller.

FIG. 10 provides an illustration of a light emitter system comprising the circuit of FIG. 8.

FIG. 11 provides a flow diagram of an illustrative method for operating a LiDAR system.

### DETAILED DESCRIPTION

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to.” Definitions for additional terms that are relevant to this document are included at the end of this Detailed Description.

An “electronic device” or a “computing device” refers to a device that includes a processor and memory. Each device may have its own processor and/or memory, or the processor and/or memory may be shared with other devices as in a virtual machine or container arrangement. The memory will contain or receive programming instructions that, when executed by the processor, cause the electronic device to perform one or more operations according to the programming instructions.

The terms “memory,” “memory device,” “data store,” “data storage facility” and the like each refer to a non-transitory device on which computer-readable data, programming instructions or both are stored. Except where specifically stated otherwise, the terms “memory,” “memory device,” “data store,” “data storage facility” and the like are intended to include single device embodiments, embodiments in which multiple memory devices together or collectively store a set of data or instructions, as well as individual sectors within such devices.

The terms “processor” and “processing device” refer to a hardware component of an electronic device that is configured to execute programming instructions. Except where specifically stated otherwise, the singular term “processor” or “processing device” is intended to include both single-processing device embodiments and embodiments in which multiple processing devices together or collectively perform a process.

The term “vehicle” refers to any moving form of conveyance that is capable of carrying either one or more human occupants and/or cargo and is powered by any form of energy. The term “vehicle” includes, but is not limited to, cars, trucks, vans, trains, autonomous vehicles, aircraft, aerial drones and the like. An “autonomous vehicle” is a vehicle having a processor, programming instructions and drivetrain components that are controllable by the processor without requiring a human operator. An autonomous vehicle may be fully autonomous in that it does not require a human operator for most or all driving conditions and functions, or it may be semi-autonomous in that a human operator may be required in certain conditions or for certain operations, or that a human operator may override the vehicle's autonomous system and may take control of the vehicle.

In this document, when terms such as “first” and “second” are used to modify a noun, such use is simply intended to distinguish one item from another, and is not intended to require a sequential order unless specifically stated. In addition, terms of relative position such as “vertical” and “horizontal”, or “front” and “rear”, when used, are intended to be relative to each other and need not be absolute, and only refer to one possible position of the device associated with those terms depending on the device's orientation.

A laser light source is one of the most important parts of a LIDAR system. The present solution uses a laser diode bar as the light source in contrast to conventional LiDAR systems that use Vertical Cavity Surface Emitting Laser (VCSEL) diode arrays or single edge emitting semiconductor lasers. The present solution has many advantages. For example, the present solution provides a LiDAR system in which: all elements of the illuminator are automatically synchronized in time; the optical power is much higher than a single semiconductor laser optical power; the laser diode bar has much higher brightness than a VCSEL light source, especially in the direction perpendicular to the wafer plane, because a laser waveguide maintains single mode operation in this direction (this allows it to form with simplest optics the laser beam with very low divergence in one direction (values less than 1 mRad (˜0.06deg) are possible)); and a single laser driver is needed to feed the laser diode bar (this increases the whole LIDAR system robustness).

The main idea of the present solution is to form a light beam with a relatively small beam divergence (e.g., ≤1 degree) in one direction (e.g., the horizontal direction) and a relatively large beam divergence (e.g., ≥10 degrees) in a second different direction (the vertical direction). For example, the light beam can have a 1 milliradian (mRad) (or 0.06 degrees) beam divergence in one direction and a 524 mRads (or 30 degrees) of beam divergence in the other direction. The present solution is not limited to the particulars of this example. The term “beam divergence” as used here refers to an angular measure of the increase in beam size with distance from the aperture of the LiDAR system from which the light beam emerges. This light beam can cover the whole Field of Interest (FOI) of the LIDAR system in a vertical direction. The horizontal sweep of the light beam will cover the FOI horizontally.

The present approach allows the illuminating pattern to match the Field of View (FOV) of the linear detector array in a LiDAR system. The main difficulties in using the laser diode bar as a light source is the required peak current values therefore. A common parallel diode bar needs about 1 killoampere (kA) pulse current. It is problematic to form such a powerful controllable current pulse with sharp edges (<0.5 ns). The present solution provides a serial laser bar that solves this problem and allows for a decrease in the current up to level about 20-50 Amperes (Amp).

The particulars of the novel laser diode bar illuminator will become evident as the discussion progresses. In this construction, the present solution may (i) locate the laser diode bar on an active cooling component, (ii) locate the diode bar driver remote from the active cooling component, and/or (iii) use a wire bridge between the laser driver and the laser diode bar. This architecture facilitates the cooling of the laser diode bar independently from the driver. The solution decreases the Thermal Electrical Cooler (TEC) power of the LiDAR system.

The present solution will be described in relation to an autonomous vehicle application. The present solution is not limited in this regard. The present solution can be employed in any application where object detection is needed.

Illustrative Systems

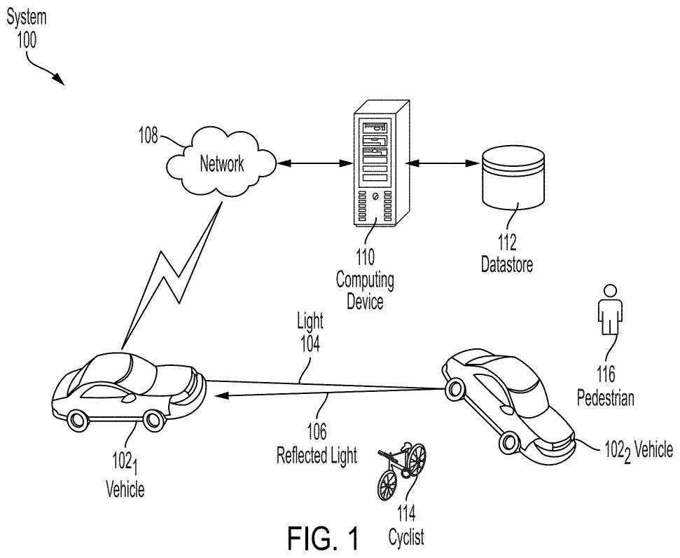

Referring now to FIG. 1, there is provided an illustration of an illustrative system 100. System 100 comprises a vehicle 102₁ that is traveling along a road in a semi-autonomous or autonomous manner. Vehicle 102₁ is also referred to herein as an Autonomous Vehicle (AV). The AV 102₁ can include, but is not limited to, a land vehicle (as shown in FIG. 1), an aircraft, or a watercraft.

AV 102₁ is generally configured to detect objects 102₂, 114, 116 in proximity thereto. The objects can include, but are not limited to, a vehicle 102₂, a cyclist 114 (such as a rider of a bicycle, electric scooter, motorcycle, or the like) and/or a pedestrian 116. The object detection is achieved using a novel LiDAR system. The novel LiDAR system will be described in detail below. When such a detection is made, AV 102₁ performs operations to: generate one or more possible object trajectories for the detected object; and analyze at least one of the generated possible object trajectories to determine whether or not there is an undesirable level of risk that a collision will occur between the AV and object in a threshold period of time (e.g., 1 minute). If so, the AV 102₁ performs operations to determine whether the collision can be avoided if a given vehicle trajectory is followed by the AV 102₁ and any one of a plurality of dynamically generated emergency maneuvers is performed in a pre-defined time period (e.g., N milliseconds). If the collision can be avoided, then the AV 102₁ takes no action or optionally performs a cautious maneuver (e.g., mildly slows down). In contrast, if the collision cannot be avoided, then the AV 102₁ immediately takes an emergency maneuver (e.g., brakes and/or changes direction of travel).

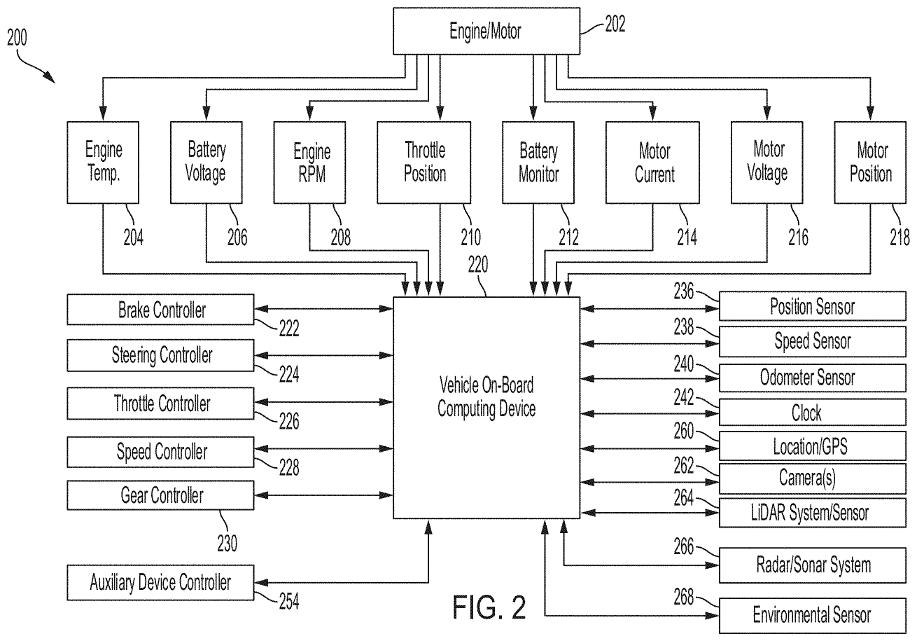

Referring now to FIG. 2, there is provided an illustration of an illustrative system architecture 200 for a vehicle. Vehicles 102₁ and/or 102₂ of FIG. 1 can have the same or similar system architecture as that shown in FIG. 2. Thus, the following discussion of system architecture 200 is sufficient for understanding vehicle(s) 102₁, 102₂ of FIG. 1.

As shown in FIG. 2, the vehicle 200 includes an engine or motor 202 and various sensors 204-218 for measuring various parameters of the vehicle. In gas-powered or hybrid vehicles having a fuel-powered engine, the sensors may include, for example, an engine temperature sensor 204, a battery voltage sensor 206, an engine Rotations Per Minute (RPM) sensor 208, and a throttle position sensor 210. If the vehicle is an electric or hybrid vehicle, then the vehicle may have an electric motor, and accordingly will have sensors such as a battery monitoring system 212 (to measure current, voltage and/or temperature of the battery), motor current 214 and voltage 216 sensors, and motor position sensors such as resolvers and encoders 218.

Operational parameter sensors that are common to both types of vehicles include, for example: a position sensor 236 such as an accelerometer, gyroscope and/or inertial measurement unit; a speed sensor 238; and an odometer sensor 240. The vehicle also may have a clock 242 that the system uses to determine vehicle time during operation. The clock 242 may be encoded into the vehicle on-board computing device, it may be a separate device, or multiple clocks may be available.

The vehicle also will include various sensors that operate to gather information about the environment in which the vehicle is traveling. These sensors may include, for example: a location sensor 260 (e.g., a Global Positioning System (GPS) device); object detection sensors such as one or more cameras 262; a LiDAR sensor system 264; and/or a radar and/or a sonar system 266. The sensors also may include environmental sensors 268 such as a precipitation sensor and/or ambient temperature sensor. The object detection sensors may enable the vehicle to detect objects that are within a given distance range of the vehicle 200 in any direction, while the environmental sensors collect data about environmental conditions within the vehicle's area of travel.

During operations, information is communicated from the sensors to an on-board computing device 220. The on-board computing device 220 analyzes the data captured by the sensors and optionally controls operations of the vehicle based on results of the analysis. For example, the on-board computing device 220 may cause the vehicle to perform autonomous driving operations such as: braking via a brake controller 232; changing direction via a steering controller 224; changing a speed and/or acceleration via a throttle controller 226 (in a gas-powered vehicle) or a motor speed controller 228 (such as a current level controller in an electric vehicle); change gears via a differential gear controller 230 (in vehicles with transmissions); and/or cause other controllers to perform operations (e.g., sensor data acquisition, analysis, object detection, trajectory planning, etc.).

Geographic location information may be communicated from the location sensor 260 to the on-board computing device 220, which may then access a map of the environment that corresponds to the location information to determine known fixed features of the environment such as streets, buildings, stop signs and/or stop/go signals. Captured images from the cameras 262 and/or object detection information captured from sensors such as LiDAR 264 is communicated from those sensors) to the on-board computing device 220. The object detection information and/or captured images are processed by the on-board computing device 220 to detect objects in proximity to the vehicle 200. Any known or to be known technique for making an object detection based on sensor data and/or captured images can be used in the embodiments disclosed in this document.

LiDAR information is communicated from LiDAR sensor 264 to the on-board computing device 220. Additionally, captured images are communicated from the camera(s) 262 to the on-board computing device 220. The LiDAR information and/or captured images are processed by the on-board computing device 220 to detect objects in proximity to the vehicle 200.

When the on-board computing device 220 detects an object, the on-board computing device 220 will generate one or more possible object trajectories for the detected object, and analyze the possible moving object trajectories to assess the risk of a collision between the object and the AV. If the risk exceeds an acceptable threshold, the on-board computing device 220 performs operations to determine whether the collision can be avoided if the AV follows a defined vehicle trajectory and/or implements one or more dynamically generated emergency maneuvers is performed in a pre-defined time period (e.g., N milliseconds). If the collision can be avoided, then the on-board computing device 220 may cause the vehicle 200 to perform a cautious maneuver (e.g., mildly slow down, accelerate, or swerve). In contrast, if the collision cannot be avoided, then the on-board computing device 220 will cause the vehicle 200 to take an emergency maneuver (e.g., brake and/or change direction of travel).

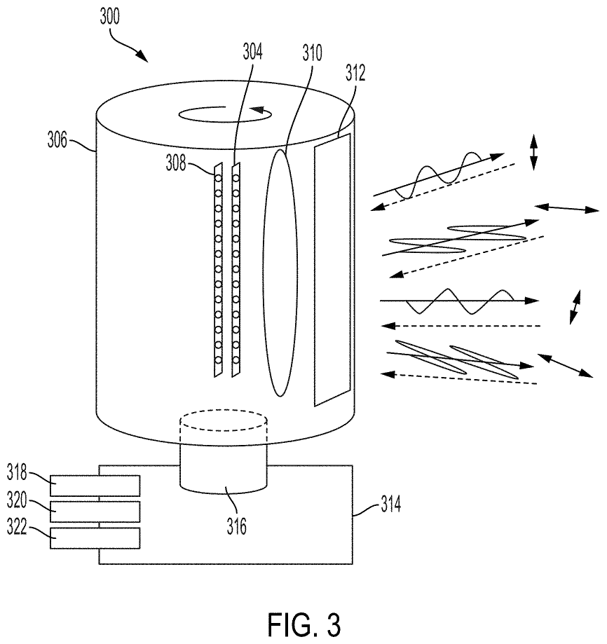

Referring now to FIG. 3, there is provided an illustration of an illustrative LiDAR system 300. LiDAR system 264 of FIG. 2 may be the same as or substantially similar to the LiDAR system 300. As such, the discussion of LiDAR system 300 is sufficient for understanding LiDAR system 264 of FIG. 2. Note that this is only one possible LIDAR construction. Other possible ways to scan can be used here, such as a rotating mirror or rotating mirror prism.

As shown in FIG. 3, the LiDAR system 300 includes a housing 306 which may be rotatable 360° about a central axis such as hub or axle 316. The housing may include an emitter/receiver aperture 312 made of a material transparent to light. Although a single aperture is shown in FIG. 2, the present solution is not limited in this regard. In other scenarios, multiple apertures for emitting and/or receiving light may be provided. Either way, the LiDAR system 300 can emit light through the aperture(s) 312 and receive reflected light back toward the aperture(s) 211 as the housing 306 rotates around the internal components. In alternative scenarios, the outer shell of housing 306 may be a stationary dome, at least partially made of a material that is transparent to light, with rotatable components inside of the housing 306.

Inside the rotating shell or stationary dome is a light emitter system 304 that is configured and positioned to generate and emit pulses of light through the aperture 312 or through the transparent dome of the housing 306 via one or more light sources. Each light source comprises a laser diode bar with a single driver. The light source emits light of substantially the same intensity or of varying intensities. The individual beams emitted by the light emitter system 304 will have a well-defined state of polarization that is not the same across the entire array. As an example, some beams may have vertical polarization and other beams may have horizontal polarization. The LiDAR system will also include a light detector 308 containing a photodetector or array of photodetectors positioned and configured to receive light reflected back into the system. The light emitter system 304 and light detector 308 would rotate with the rotating shell, or they would rotate inside the stationary dome of the housing 306. One or more optical element structures 310 may be positioned in front of the light emitting unit 304 and/or the light detector 308 to serve as one or more lenses or waveplates that focus and direct light that is passed through the optical element structure 310.

One or more optical element structures 310 may be positioned in front of a window to focus and direct light that is passed through the optical element structure 310. As shown in FIG. 3, the system includes an optical element structure 310 positioned in front of the window and connected to the rotating elements of the system so that the optical element structure 310 rotates with the window. Alternatively or additionally, the optical element structure 310 may include multiple such structures (for example lenses and/or waveplates). Optionally, multiple optical element structures 310 may be arranged in an array on or integral with the shell portion of the housing 306.

Optionally, each optical element structure 310 may include a beam splitter that separates light that the system receives from light that the system generates. The beam splitter may include, for example, a quarter-wave or half-wave waveplate to perform the separation and ensure that received light is directed to the receiver unit rather than to the emitter system (which could occur without such a waveplate as the emitted light and received light should exhibit the same or similar polarizations).

The LiDAR system will include a power unit 318 to power the light emitter system 304, a motor 316, and electronic components. The LiDAR system will also include an analyzer 314 with elements such as a processor 322 and non-transitory computer-readable memory 320 containing programming instructions that are configured to enable the system to receive data collected by the light detector unit, analyze it to measure characteristics of the light received, and generate information that a connected system can use to make decisions about operating in an environment from which the data was collected. Optionally, the analyzer 314 may be integral with the LiDAR system 300 as shown, or some or all of it may be external to the LiDAR system and communicatively connected to the LiDAR system via a wired or wireless communication network or link.

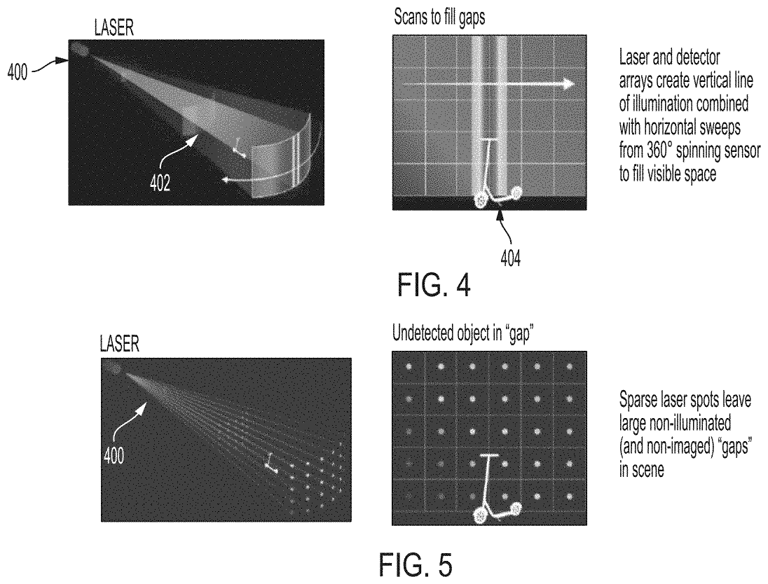

Referring now to FIGS. 4-5, there are provided illustrations that are useful for understanding operations of a conventional LiDAR system 300 in object detection applications. The LiDAR system 400 comprises a group of emitters that emit light 402 in a direction towards an object 404 (e.g., a scooter). Multiple driver circuits are provided for the emitters. The light 402 is reflected off of the object. The reflected light is received by a light detector of the LiDAR system 400. The LiDAR system 400 creates a vertical line of illumination combined with horizontal sweeps from 360° spinning sensor to fill visible space. Sparse laser spots leave large non-illuminated (and non-imaged) gaps in the scene, as shown by FIG. 5. Thus, objects that reside in the gaps are not detected by the conventional system.

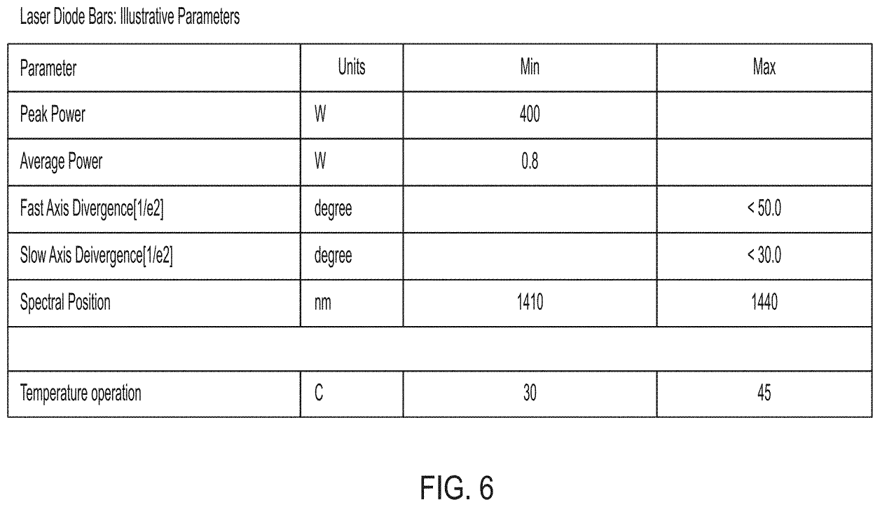

The present solution is designed to address this issue via implementation of a LiDAR system comprising a light emitter system 304 employing a laser diode bar with a single driver circuit (instead of a group of emitters with multiple drivers). The laser diode bar is arranged to form a high-power semiconductor laser containing an array of broad-area emitters. The laser diode bar can contain any number of emitters selected in accordance with a given application (e.g., 20-50 emitters). The laser diode bar is designed to have certain parameters to facilitate improved long-range and short-range object detection. Illustrative laser diode bar parameters for combined long/short-range detection applications are shown in FIG. 6.

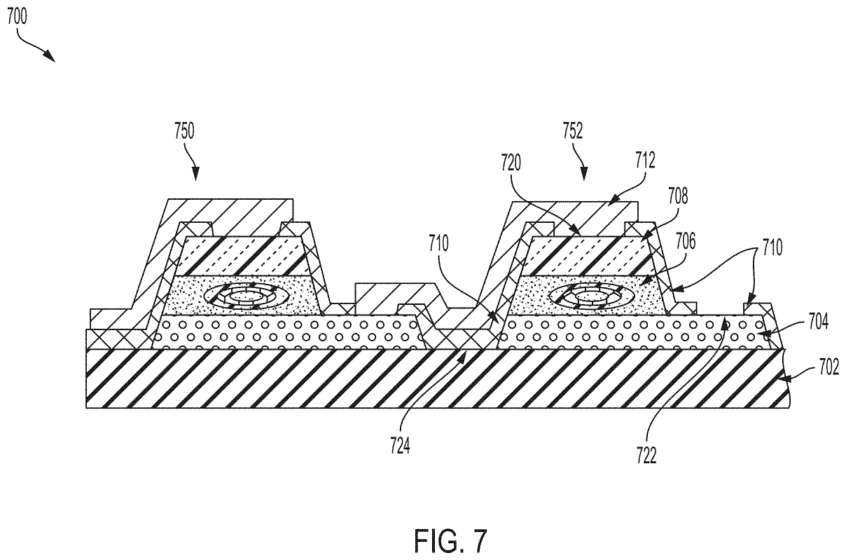

FIG. 7 provides an illustrative architecture for a serial laser diode bar 700. The serial laser diode bar 700 comprises a plurality of laser diodes 750, 752 (e.g., 30-50 laser diodes) disposed on a semiconductor substrate 702 and connected in series with each other. The semiconductor substrate 702 is formed of an insulative material. The substrate 702 can include, but is not limited to, an Indium Phosphide (InP) material.

Each laser diode 750, 752 comprises an N-type semiconductor material 704 that is disposed on the substrate 702. An intrinsic compound semiconductor material 706 is disposed on the N-type semiconductor material 704. A P-type semiconductor material 708 is disposed on the intrinsic compound semiconductor material 706. An insulative material 710 and a conductive material 712 are disposed on the stacked structures 702-708 to facilitate the provision of the serial connection between the adjacent laser diodes 750, 752. More specifically, the insulative material 710 is first disposed on (i) each stacked structure 702-708 such that only select portions or surfaces 720, 722 thereof are exposed and (ii) on portions 724 of the semiconductor substrate 702 that reside between adjacent stacked structures 707-708. Next, the conductive material 712 is disposed on the assembly so as to electrically connect the surface 720 of a P-type semiconductor material 708 of laser diode 752 and a surface 722 of the N-type semiconductor material 704 of the adjacent laser diode 750 to each other.

The refractive index of the intrinsic compound semiconductor material 706 is different than that of the other materials. Material 706 provides an active region of the laser diode. This active region acts as a waveguide that allows light to propagate there along in a direction perpendicular to the direction of current and be emitted from the laser diode.

Notably, conventional laser diode bars comprise laser diodes that are connected in parallel. In contrast, the present solution comprises a laser diode bar with laser diodes connected in series. This series connection allows decreased current in the light source which results in improved LiDAR system performance.

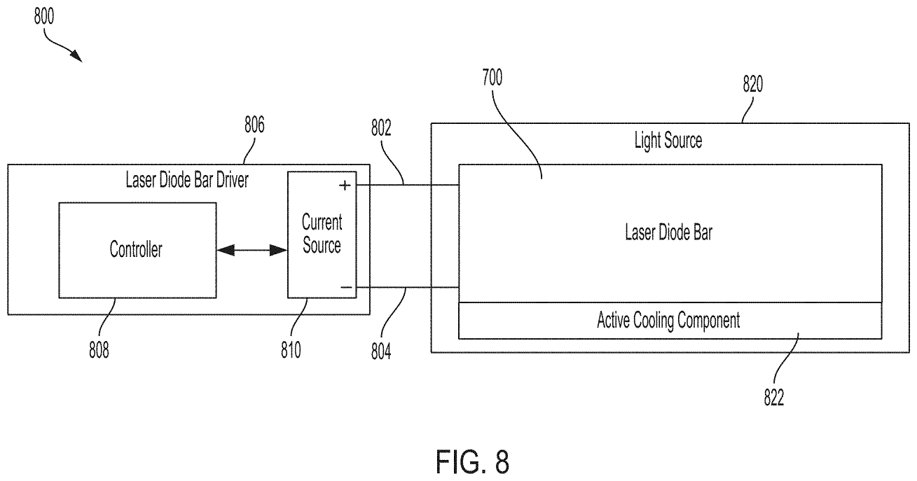

FIG. 8 provides an illustration of a circuit 800 including a laser diode bar driver 806 and a light source 820 (e.g., light emitter system 304 of FIG. 3). The light source 820 comprises the serial laser diode bar 700 of FIG. 7. The serial laser diode bar 700 is connected between input lines 802, 804. The input lines 802, 804 may comprise wires forming a wire bridge between the serial laser diode bar 700 and a laser diode bar driver 806. The serial laser diode bar 700 is disposed on an active cooling component 822 such that it can be cooled independently from the laser diode bar driver 806 (which is located remote from the active cooling component). In effect, the TEC power is reduced in circuit 800 and/or a LiDAR system (e.g., LiDAR system 264 of FIG. 2) in which circuit 800 is employed. The active cooling component can include, but is not limited to, a thermoelectric cooler (TEC). TECs are well known.

The laser diode bar driver 806 comprises a controller 808 and a current source 810. The controller 808 controls operations of the current source 810. For example, the controller 808 is configured to selectively turn on/off the current source 810, and/or selectively electrically connect/disconnect the current source 810 to/from the serial laser diode bar 700 (e.g., via one or more switches).

During operation, the serial laser diode bar driver 806 selectively provides a current signal to the serial laser diode bar 700 via lines 802, 804 for activating and deactivating the circuit 800. Light is generated by and emitted from the serial laser diode bar 700 when the current signal is supplied thereto. The light is no longer emitted from the serial laser diode bar 700 when supply of the current signal is discontinued.

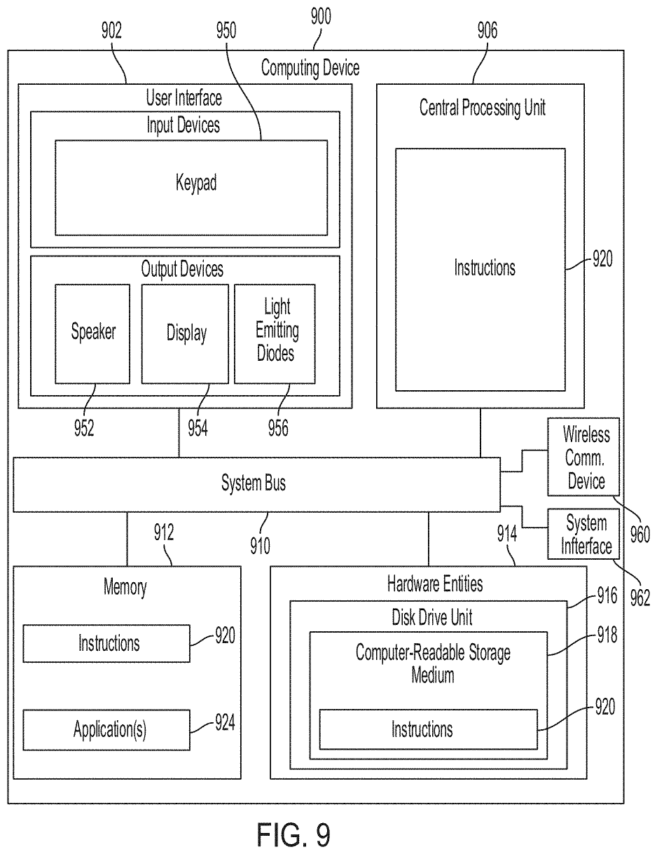

An illustration of an architecture for a controller 900 is provided in FIG. 9. Controller 808 can be the same as or similar to controller 900. Computing device 110 of FIG. 1 and/or vehicle on-board computing device 220 of FIG. 2 may also be the same as or similar to controller 900. Thus, the discussion of controller 900 is sufficient for understanding controller 808 of FIG. 8, computing device 100 of FIG. 1 and/or vehicle on-board computing device 220 of FIG. 2.

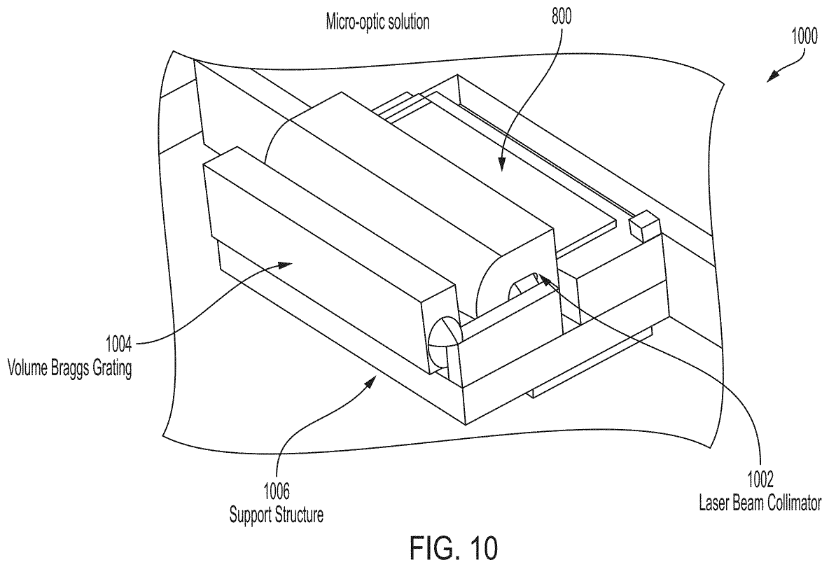

Controller 900 may include more or less components than those shown in FIG. 9. However, the components shown are sufficient to disclose an illustrative embodiment implementing the present solution. The hardware architecture of FIG. 9 represents one embodiment of a representative controller configured to facilitate control of a diode bar (e.g., serial laser diode bar 700 of FIG. 7). As such, the controller 900 of FIG. 9 implements at least a portion of the methods described herein for controlling operations of a diode bar (e.g., serial laser diode bar 700 of FIG. 7), a LiDAR system (e.g., LiDAR system 264 of FIG. 2), and/or a light emitter system (e.g., light emitter system 1000 of FIG. 10).

Some or all the components of the controller 900 can be implemented as hardware, software and/or a combination of hardware and software. The hardware includes, but is not limited to, one or more electronic circuits. The electronic circuits can include, but are not limited to, passive components (e.g., resistors, capacitors, inductors, etc.) and/or active components (e.g., amplifiers, microprocessors, logic gates, operational amplifiers, etc.). The passive and/or active components can be adapted to, arranged to and/or programmed to perform one or more of the methodologies, procedures, or functions described herein.

As shown in FIG. 9, the controller 900 comprises a user interface 902, a CPU 906, a system bus 910, a memory 912 connected to and accessible by other portions of controller 900 through system bus 910, and hardware entities 914 connected to system bus 910. The user interface can include input devices (e.g., a keypad 950) and output devices (e.g., speaker 952, a display 954, and/or light emitting diodes 956), which facilitate user-software interactions for controlling operations of the controller 900.

At least some of the hardware entities 914 perform actions involving access to and use of memory 912, which can be a RAM. Hardware entities 914 can include a disk drive unit 916 comprising a computer-readable storage medium 918 on which is stored one or more sets of instructions 920 (e.g., software code) configured to implement one or more of the methodologies, procedures, or functions described herein. The instructions 920 can also reside, completely or at least partially, within the memory 912 and/or within the CPU 906 during execution thereof by the controller 900. The memory 912 and the CPU 906 also can constitute machine-readable media. The term “machine-readable media”, as used here, refers to a single medium or multiple media (e.g., a centralized or distributed database, and/or associated caches and servers) that store the one or more sets of instructions 920. The term “machine-readable media”, as used here, also refers to any medium that is capable of storing, encoding or carrying a set of instructions 920 for execution by the controller 900 and that cause the controller 900 to perform any one or more of the methodologies of the present disclosure.

In some scenarios, the hardware entities 914 include an electronic circuit (e.g., a processor) programmed for facilitating the control of a laser bar, a light emitter system and/or LiDAR system. In this regard, it should be understood that the electronic circuit can access and run a software application 922 installed on the controller 900.

A wireless communication device 960 and/or a system interface 962 may also be provided with the controller 900. The wireless communication device 960 is configured to facilitate wireless communications between the controller 900 and external devices (e.g., the vehicle on-board computing device 220 of FIG. 2 and/or computing device 110 of FIG. 1). The wireless communications can include, but are not limited to, Near Field Communications (NFCs), Short Range Communications (SRCs) (e.g., WiFi, Bluetooth, and/or LoRA), and/or Long Range Communications (LRCs) (e.g., satellite communications, radio communications and/or cellular communications). The system interface 962 is configured to facilitate wired and/or wireless communications between the controller 900 and external devices. In this regard, the system interface 962 can include, but is not limited to, an Ethernet interface, an RS232 interface, an RS422 interface, and/or a USB interface.

Referring now to FIG. 10, there is provided an illustration of a light emitter system 1000 which implements the circuit 800 of FIG. 8. Light emitter system 304 of FIG. 3 can be the same as or similar to light emitter system 1000. The circuit 800 is disposed on a support structure 1006 along with a laser beam collimator 1002 and a volume Bragg grating 1004. Laser beam collimators and volume Bragg gratings are well known. The laser beam collimator 1002 is generally configured to form a narrow laser beam from light beams emitted from the laser diodes of the circuit 800. The volume Bragg grating 1004 is generally configured to stabilize a wavelength of the narrow laser beam.

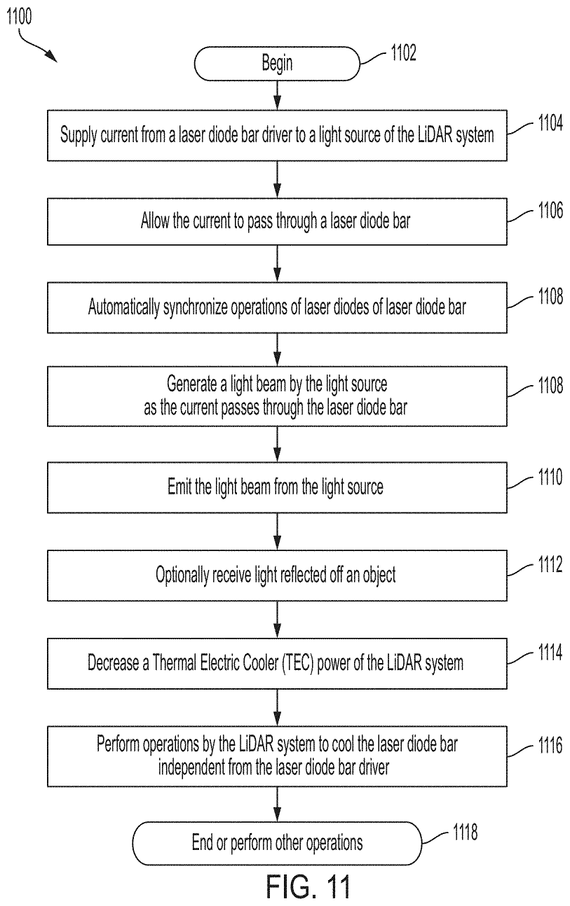

Referring now to FIG. 11, there is provided a flow diagram of an illustrative method 1100 for operating a LiDAR system (e.g., LiDAR system 264 of FIG. 2 and/or 300 of FIG. 3). Method 1100 begins with 1102 and continues with 1104 where current is supplied from a laser diode bar driver (e.g., laser diode bar driver 806 of FIG. 8) of the LiDAR system to a light source (e.g., light emitter system 304 of FIG. 3 and/or light source 820 of FIG. 8) of the LiDAR system. The current may be less than 100 Amperes in some scenarios.

In 1106, the current is allowed to pass through a laser diode bar (e.g., serial laser diode bar 700 of FIG. 7). The laser diode bar comprises a plurality of laser diodes (e.g., laser diodes 750, 752 of FIG. 7) that are electrically connected to each other in series. Operations of the laser diodes are automatically synchronized in time as shown by 1108. This synchronization is as a result from the laser diodes being electrically connected in series rather than the independent laser diodes.

A light beam is generated by the light source in 1108 as the current passes through the laser diodes. The light beam is emitted from the light source in 1110. In 1112, the LiDAR system optionally receives light reflected off an object (e.g., vehicle 102₂ of FIG. 1, cyclist 114 of FIG. 1, or pedestrian 116 of FIG. 1). In some scenarios, the light beam may have a beam divergence less than or equal to one degree in a first direction, and a beam divergence greater than or equal to ten degrees in a second different direction.

In 1114, a TEC power of the LiDAR system is decreased by locating the laser diode bar on an active cooling component and locating the laser diode bar driver remote from the active cooling component. A wire bridge may be used to connect the laser diode bar to the laser diode bar driver. This architecture allows the laser diode bar to be cooled independently from the laser diode bar driver. The cooling of the laser diode bar can be achieved by using a TEC as the active cooling component. Subsequently, 1118 is performed where method 1100 ends or other operations are performed (e.g., return to 1102).

Although the present solution has been illustrated and described with respect to one or more implementations, equivalent alterations and modifications will occur to others skilled in the art upon the reading and understanding of this specification and the annexed drawings. In addition, while a particular feature of the present solution may have been disclosed with respect to only one of several implementations, such feature may be combined with one or more other features of the other implementations as may be desired and advantageous for any given or particular application. Thus, the breadth and scope of the present solution should not be limited by any of the above described embodiments. Rather, the scope of the present solution should be defined in accordance with the following claims and their equivalents.

What is claimed is:

1. A LiDAR system, comprising:
a light emitter system configured to emit light therefrom and comprising a laser diode bar formed of a plurality of laser diodes; and
a driver circuit configured to supply current to the light emitter system;
wherein the light emitter system is configured to generate the light as the current passes through the laser diode bar.

2. The LiDAR system of claim 1, wherein the plurality of laser diodes are electrically connected to each other in series.

3. The LiDAR system of claim 1, wherein each laser diode comprise a stack of layers disposed on a semiconductor substrate formed of an insulative material.

4. The LiDAR system of claim 3, wherein the stack of layers comprises a first layer formed of an N-type semiconductor material disposed on the semiconductor substrate, a second layer formed of an intrinsic compound semiconductor material disposed on the first layer, a third layer formed of a P-type semiconductor material disposed on the second layer.

5. The LiDAR system of claim 3, wherein an insulative material and a conductive material are disposed on the stack of layers to electrically connect a first laser diode of the plurality of laser diodes in series with a second laser diode of the plurality of laser diodes.

6. The LiDAR system of claim 5, wherein the conductive material connects the P-type semiconductor material of the first laser diode to the N-type semiconductor material of the second laser diode.

7. The LiDAR system of claim 1, wherein the driver circuit is connected to the laser diode bar.

8. The LiDAR system of claim 7, wherein the laser diode bar is configured to be cooled independently from the driver circuit.

9. The LiDAR system of claim 1, wherein operations of the plurality of laser diodes are automatically synchronized in time.

10. A system, comprising:
a LiDAR system configured to generate LiDAR data sets, the LiDAR system comprising:
a driver circuit configured to supply current to a light emitter system; and
the light emitter system comprising a laser diode bar formed of a plurality of laser diodes, wherein the light emitter system is configured to generate light when the current passes through the laser diode bar; and
a computing device configured to issue a command that causes a vehicle to perform operations based on the LiDAR data sets.

11. The system of claim 10, wherein the plurality of laser diodes is connected to each other in series.

12. The system of claim 10, wherein each laser diode comprise a stack of layers disposed on a semiconductor substrate formed of an insulative material.

13. The system of claim 10, wherein the stack of layers comprises a first layer formed of an N-type semiconductor material disposed on the semiconductor substrate, a second layer formed of an intrinsic compound semiconductor material disposed on the first layer, a third layer formed of a P-type semiconductor material disposed on the second layer.

14. The system of claim 10, wherein an insulative material and a conductive material are disposed on the stack of layers to electrically connect a first laser diode of the plurality of laser diodes in series with a second laser diode of the plurality of laser diodes.

15. The system of claim 14, wherein the conductive material connects a P-type semiconductor material of the first laser diode to a N-type semiconductor material of the second laser diode.

16. The system of claim 10, wherein the driver circuit is connected to the laser diode bar.

17. The system of claim 10, wherein operations of the plurality of laser diodes are automatically synchronized in time.

18. A method for operating a LiDAR system, comprising:
supplying current from a laser diode bar driver of the LiDAR system to a light source of the LiDAR system;
passing the current through a laser diode bar of the light source, the laser diode bar comprising a plurality of laser diodes electrically connected in series; and
emitting a light beam from the light source when the current is passing through the plurality of laser diodes.

19. The method according to claim 18, wherein operations of the plurality of laser diodes are automatically synchronized in time.

20. The method according to claim 18, wherein the light beam has a beam divergence less than or equal to one degree in a first direction and a beam divergence greater than or equal to ten degrees in a second different direction.
